(19) United States
(12) Patent Application Publication
(10) Pub. No.: US 2026/0143685 A1
(43) Pub. Date: May 21, 2026

(54) METHOD FOR MANUFACTURING SEMICONDUCTOR STRUCTURE AND SEMICONDUCTOR STRUCTURE

(71) Applicant: CXMT Corporation, Hefei (CN)

(72) Inventors: Jiacun He, Hefei (CN); Yang Zhou, Hefei (CN); Mengjie Wang, Hefei (CN); Fukang Chen, Hefei (CN)

(73) Assignee: CXMT Corporation, Hefei (CN)

(21) Appl. No.: 19/234,913

(22) Filed: Jun. 11, 2025

Related U.S. Application Data
(63) Continuation of application No. PCT/CN2025/082241, filed on Mar. 13, 2025.

(30) Foreign Application Priority Data
Nov. 19, 2024 (CN) 202411653149.X

(51) Int. Cl. H10B 12/00

(52) U.S. Cl. CPC H10B 12/482; H10B 12/02

(57) ABSTRACT

Disclosed a method includes a base substrate, bit line structures and first openings. A first initial material layer covers the bit line structures. A first material layer, the thickness of the first material layer increases from the top of the bit line structure to a first position at a first rate and increases from the first position to the bottom of the first material layer at a second rate. A second material layer covers the first material layer. A first initial dielectric layer fills portions of the first openings; part of the first initial dielectric layer is removed to form second openings and first dielectric layers. A second dielectric layer fills the second openings. The first dielectric layers are removed to form third openings. The first material layer and the second material layer above the first position are removed, and node contact holes are formed.

### CROSS-REFERENCE

This application is a continuation of International Patent Application No. PCT/CN2025/082241, filed on Mar. 13, 2025, which claims the benefit of Chinese Patent Application No. 202411653149.X, titled “METHOD FOR MANUFACTURING SEMICONDUCTOR STRUCTURE AND SEMICONDUCTOR STRUCTURE”, filed with the China National Intellectual Property Administration (CNIPA) on Nov. 19, 2024, the disclosures of which are incorporated herein by reference in their entireties.

### TECHNICAL FIELD

Embodiments of the present disclosure relate to the field of semiconductors, in particular to a method for manufacturing a semiconductor structure and a semiconductor structure.

### BACKGROUND

In the manufacturing process of dynamic random access memories (DRAMs), as chip dimensions continue to shrink, the challenges in the process are increasingly significant. Due to the shrinkage, air gaps are present in the contact structure or the conductive structure, which may cause performance degradation of the conductive structure or the contact structure.

### SUMMARY

Embodiments of the present disclosure provide a method for manufacturing a semiconductor structure and a semiconductor structure, which at least helps to solve the problem of the presence of air gaps in a conductive structure or a contact structure that may lead to degraded performance of the conductive structure or contact structure.

According to some embodiments of the present disclosure, an aspect of the embodiments of the present disclosure provides a method for manufacturing a semiconductor structure. The method includes:
providing a base substrate;
forming bit line structures on the base substrate, where the bit line structures extend along a first direction and are spaced apart from each other along a second direction, the first direction is perpendicular to the second direction, and first openings are provided between adjacent bit line structures;
forming a first initial material layer, where the first initial material layer covers side walls and tops of the bit line structures and bottoms of the first openings;
removing part of the first initial material layer by a first etching process to form a first material layer, where a thickness of the first material layer gradually increases from each of the tops of each of the bit line structures to a first position at a first rate and gradually increases from the first position to a bottom of the first material layer at a second rate; the first rate is greater than the second rate;
forming a second material layer, where the second material layer covers the first material layer;
forming a first initial dielectric layer, the first initial dielectric layer filling remaining portions of the first openings; removing part of the first initial dielectric layer to form second openings, where remaining first initial dielectric layers serve as first dielectric layers, and the first dielectric layers and the second openings are located between adjacent bit line structures and spaced apart from each other along the first direction;
forming a second dielectric layer, where the second dielectric layer fills the second openings;
removing the first dielectric layers to form third openings, where the third openings are located between adjacent bit line structures, and the third openings and the second dielectric layer are spaced apart from each other along the first direction; and
performing etching by a second etching process with the third openings as a mask to remove the first material layer and the second material layer above the first position and form fourth openings under the third openings, where each of the third openings and each of the fourth openings together constitute a node contact hole.

Another aspect of the embodiments of the present disclosure further provides a semiconductor structure. The semiconductor structure includes: a base substrate;
bit line structures, formed on the base substrate, where the bit line structures extend along a first direction and are spaced apart from each other along a second direction, the first direction being perpendicular to the second direction;
third openings and a second dielectric layer, provided between adjacent bit line structures, where the third openings and the second dielectric layer are spaced apart from each other along the first direction;
fourth openings, formed under the third openings, where each of the third openings and each of the fourth openings together constitute a node contact hole;
a first material layer, covering side walls of the bit line structures, where the first material layer extends from a first position of each of the bit line structures to a bottom of the bit line structure; and
a second material layer, covering the first material layer, the bit line structure from a top to the first position is not covered by the first material layer and the second material layer.

The technical solutions provided by the embodiments of the present disclosure at least have the following advantages: Part of the first initial material layer is removed by a first etching process to form a first material layer, and the thickness of the first material layer gradually increases from the top of the bit line structure to a first position at a first rate and gradually increases from the first position to the bottom of the first material layer at a second rate; the first rate is greater than the second rate; the first material layer and the second material layer above the first position are removed by a second etching process, a fourth opening is formed under a third opening, and the third opening and the fourth opening together constitute a node contact hole, such that the top opening of the node contact hole is enlarged, thereby preventing the generation of air gaps when the contact structure, the bonding structure, and the conductive structure are formed by subsequent filling, and thus improving the conductive performance of the conductive structure and the contact structure.

### BRIEF DESCRIPTION OF DRAWINGS

One or more embodiments are exemplarily illustrated with reference to figures in the corresponding drawings, and these exemplary illustrations are not to be construed as limiting the embodiments. Unless expressly stated otherwise, the figures in the drawings do not constitute a limitation of scale. To more clearly illustrate the technical solutions in the embodiments of the present disclosure or conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1 is a schematic view of a semiconductor structure according to an embodiment of the present disclosure;

FIG. 2 is a schematic view of a method for forming a semiconductor structure according to an embodiment of the present disclosure;

FIG. 3 is a schematic top view of a semiconductor structure according to an embodiment of the present disclosure; and

FIGS. 4A to 18B are process flow diagrams for a method for forming a semiconductor structure according to an embodiment of the present disclosure, where FIGS. 4A, 5A, 6A, 7A, 9A, 10A, 11A, 12A, 13A, 14A, 15A, 16A, 17A, and 18A are cross-sectional views along the direction B-B′ in FIG. 3; FIGS. 4B, 5B, 6B, 7B, 9B, 10B, 11B, 12B, 13B, 14B, 15B, 16B, 17B, and 18B are cross-sectional views along the direction D-D′ in FIG. 3; FIG. 8 is an enlarged view of a part circled in FIG. 7A; FIG. 12C is a schematic top view of FIG. 12A; FIG. 13C is a schematic top view of FIG. 13A; and FIG. 14C is a schematic top view of FIG. 14A.

### DESCRIPTION OF EMBODIMENTS

It can be known from the background section that in the manufacturing process of dynamic random access memories (DRAMs), as chip dimensions continue to shrink, the challenges in the process are increasingly significant. Due to the shrinkage, air gaps are present in the contact structure or the conductive structure, which may cause performance degradation of the conductive structure or the contact structure.

The embodiments of the present disclosure provide a method for manufacturing a semiconductor structure. Part of a first initial material layer is removed by a first etching process to form a first material layer, and the thickness of the first material layer gradually increases from the top of a bit line structure to a first position at a first rate and gradually increases from the first position to the bottom of the first material layer at a second rate; the first rate is greater than the second rate; a second material layer is formed, and the second material layer covers the first material layer; the first material layer and the second material layer above the first position are removed by a second etching process, a fourth opening is formed under a third opening, and the third opening and the fourth opening together constitute a node contact hole, such that the top opening of the node contact hole is enlarged, thereby preventing the generation of air gaps when a contact structure, a bonding structure, and a conductive structure are formed by subsequent filling, and thus improving the conductive performance of the conductive structure and the contact structure.

The embodiments of the present disclosure will be described in detail below with reference to the drawings. However, those of ordinary skill in the art can understand that, in the embodiments of the present disclosure, numerous technical details are set forth to enable readers to better understand the present disclosure. However, the technical solutions claimed by the present disclosure can also be implemented even without these technical details and the various changes and modifications based on the following embodiments.

The present disclosure is more specifically described in the following paragraphs with reference to the drawings by way of example. The advantages and features of the present disclosure will become apparent from the following description and claims. It should be noted that the drawings are all in a very simplified form and not to a precise scale, and are provided only for the purpose of facilitating a convenient and clear description of the embodiments of the present disclosure.

It will be understood that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material part that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be located between the top surface and the bottom surface of a continuous structure, or a layer may be located between any pair of horizontal planes at the top surface and the bottom surface of the continuous structure. A layer may extend horizontally, perpendicularly, and/or along inclined surfaces. A layer may include a plurality of sub-layers.

It should be noted that unless conflicting, the technical solutions described in the embodiments of the present disclosure may be arbitrarily combined.

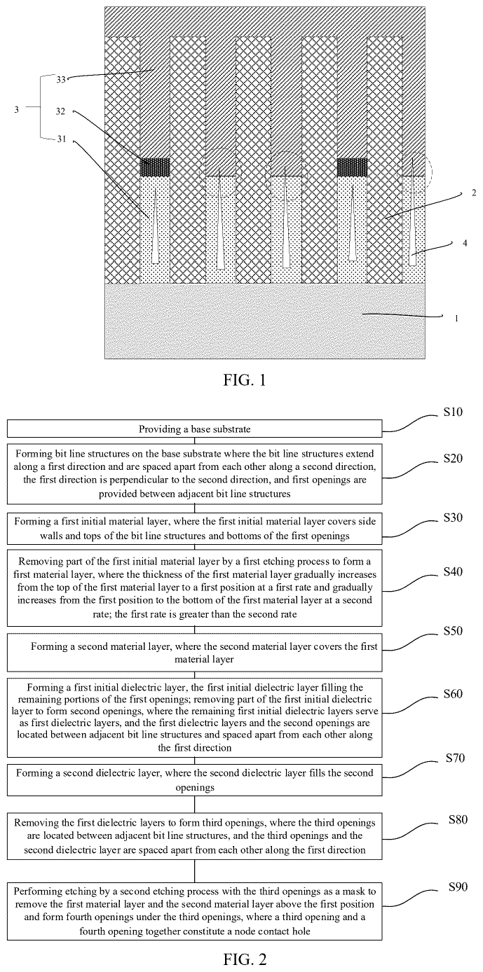

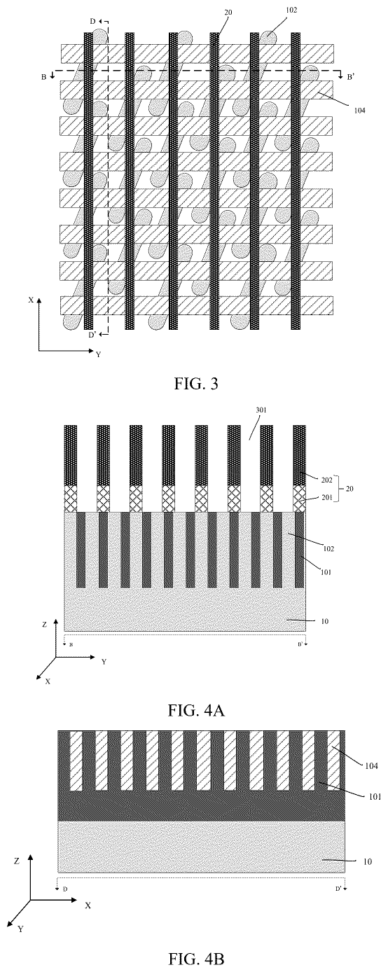

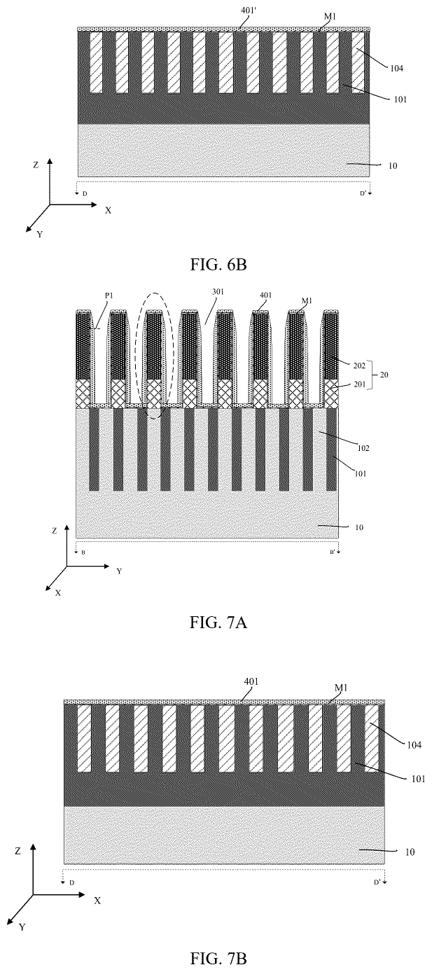

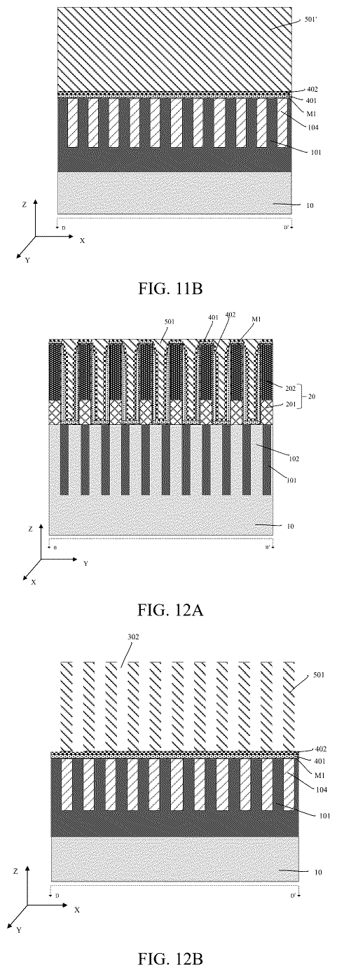

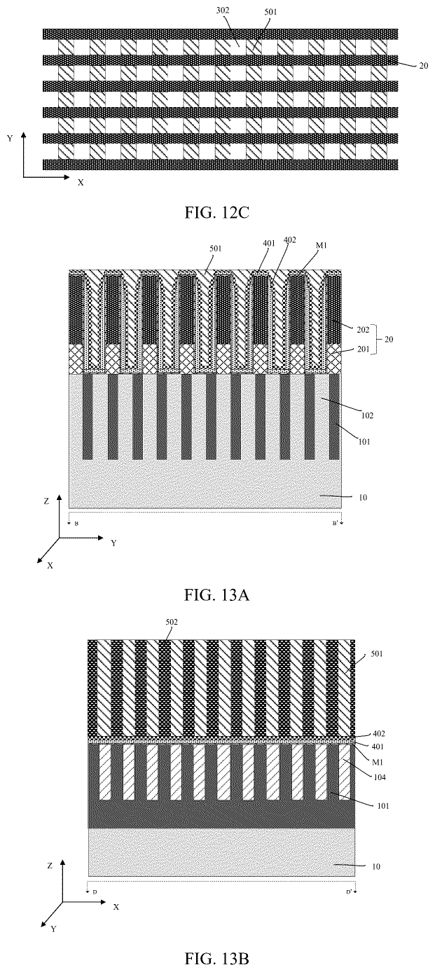

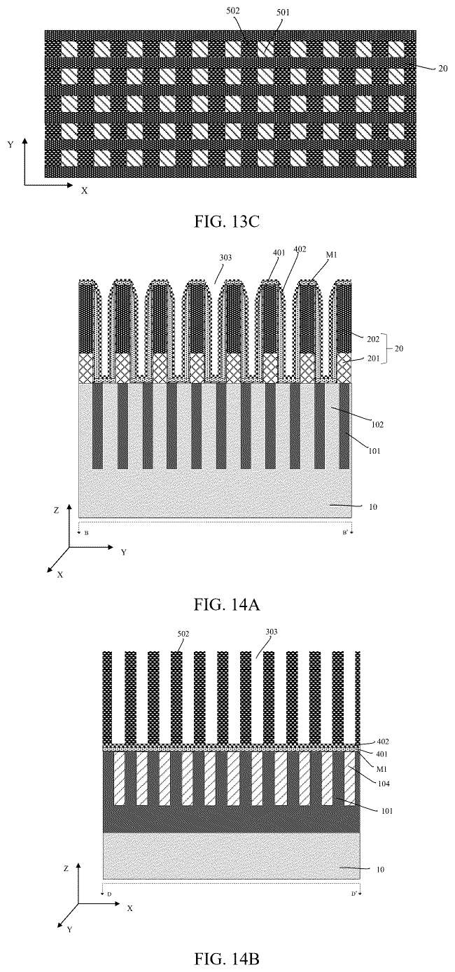

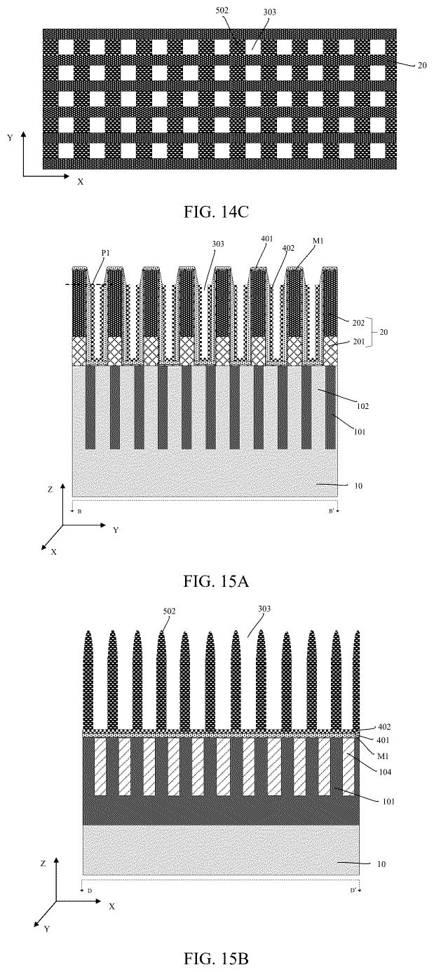

FIG. 1 is a schematic view of a semiconductor structure according to an embodiment of the present disclosure; FIG. 2 is a schematic view of a method for forming a semiconductor structure according to an embodiment of the present disclosure; FIG. 3 is a schematic top view of a semiconductor structure according to an embodiment of the present disclosure; and FIGS. 4A to 18B are process flow diagrams for a method for forming a semiconductor structure according to an embodiment of the disclosure, where FIGS. 4A, 5A, 6A, 7A, 9A, 10A, 11A, 12A, 13A, 14A, 15A, 16A, 17A, and 18A are cross-sectional views along the direction B-B′ in FIG. 3; FIGS. 4B, 5B, 6B, 7B, 9B, 10B, 11B, 12B, 13B, 14B, 15B, 16B, 17B, and 18B are cross-sectional views along the direction D-D′ in FIG. 3; FIG. 8 is an enlarged view of a part circled in FIG. 7A; FIG. 12C is a schematic top view of FIG. 12A; FIG. 13C is a schematic top view of FIG. 13A; and FIG. 14C is a schematic top view of FIG. 14A.

FIG. 1 is a schematic view of a semiconductor structure according to an embodiment of the present disclosure. The semiconductor structure includes: a base substrate 1; bit line structures 2, provided on the base substrate 1; and connecting structures 3, which fill adjacent bit line structures 2. The connecting structure 3 includes a contact structure 31, a bonding structure 32, and a conductive structure 33 in sequence from bottom to top. The bonding structure 32 is located between the contact structure 31 and the conductive structure 33, and the conductive structure 33 further covers the top of the bit line structure 2. Air gaps 4 are present in the contact structure 31, and some of the air gaps 4 are present in both the contact structure 31 and the conductive structure 33. When the air gap 4 is present in the contact structure 31, not only the conductive performance of the contact structure 31 is affected, but the formation of the bonding structure 32 is also affected by the presence of the air gap 4. As a result, the bonding structure 32 which should have been generated between the contact structure 31 and the conductive structure 33 cannot be formed, leading to the disappearance of the bonding structure 32. This phenomenon affects the conductive performance of the contact structure 31 and the conductive structure 33 as well as the overall performance of the semiconductor structure. As shown by the dashed circle in FIG. 1, it is the location where the bonding structure 32 should have been generated but was not generated. The bonding structure 32 is generated by the reaction between a reactive gas and the contact structure 31. The disappearance of the bonding structure 32 is primarily due to the presence of the air gap 4, which causes the surface of the contact structure 31 to be uneven, making the reaction difficult to proceed and ultimately leading to the disappearance of the bonding structure 32.

To solve the above problems, the present disclosure provides a semiconductor structure and a method for manufacturing a semiconductor structure, specifically referring to FIGS. 2 to 18B. FIG. 2 is a schematic view of a method for forming a semiconductor structure according to an embodiment of the present disclosure, and FIG. 3 is a schematic top view of a semiconductor structure according to an embodiment of the disclosure.

Referring to FIG. 2, FIG. 2 illustrates a method for manufacturing a semiconductor structure according to an embodiment of the present disclosure. The method specifically includes: step S10, providing a base substrate; step S20, forming bit line structures on the base substrate, where the bit line structures extend along a first direction and are spaced apart from each other along a second direction, the first direction is perpendicular to the second direction, and first openings are provided between adjacent bit line structures; step S30, forming a first initial material layer, where the first initial material layer covers the side walls and tops of the bit line structures and the bottoms of the first openings; step S40, removing part of the first initial material layer by a first etching process to form a first material layer, where the thickness of the first material layer gradually increases from the top of the bit line structure to a first position at a first rate and gradually increases from the first position to the bottom of the first material layer at a second rate, the first rate being greater than the second rate; step S50, forming a second material layer, where the second material layer covers the first material layer; step S60, forming a first initial dielectric layer, the first initial dielectric layer filling the remaining portions of the first openings; and removing part of the first initial dielectric layer to form second openings, the remaining first initial dielectric layers serving as first dielectric layers, and the first dielectric layers and the second openings being located between adjacent bit line structures and spaced apart from each other along the first direction; step S70, forming a second dielectric layer, the second dielectric layer filling the second openings; step S80, removing the first dielectric layer to form third openings, where the third openings are located between adjacent bit line structures, and the third openings and the second dielectric layer are spaced apart from each other along the first direction; and step S90, performing etching by using a second etching process with the third openings as a mask to remove the first material layer and the second material layer above the first position and form fourth openings under the third openings, a third opening and a fourth opening together constituting a node contact hole.

FIG. 3 is a schematic top view of a semiconductor structure according to an embodiment of the present disclosure. Referring to FIG. 3, for convenience of subsequent description, a schematic top view of a semiconductor structure is provided here. The semiconductor structure includes active regions 102, where the active regions 102 extend along a certain inclined direction, a plurality of active regions 102 are spaced apart from each other along both the extending direction and a direction perpendicular to the extending direction, and a blank region between adjacent active regions 102 is an isolation structure (not shown in the figure); word line structures 104, where the word line structures pass through the plurality of active regions 102, the word line structures 104 extend along the second direction Y, and adjacent word line structures 104 are spaced apart from each other along the first direction X; bit line structures 20, where the bit line structures extend along a first direction X, and a plurality of bit line structures 20 are spaced apart from each other along the second direction Y.

FIGS. 4A to 18B are process flow diagrams for a method for forming a semiconductor structure according to an embodiment of the present disclosure, where FIGS. 4A, 5A, 6A, 7A, 9A, 10A, 11A, 12A, 13A, 14A, 15A, 16A, 17A, and 18A are cross-sectional views along the direction B-B′ in FIG. 3; FIGS. 4B, 5B, 6B, 7B, 9B, 10B, 11B, 12B, 13B, 14B, 15B, 16B, 17B, and 18B are cross-sectional views along the direction D-D′ in FIG. 3; FIG. 12C is a schematic top view of FIG. 12A; FIG. 13C is a schematic top view of FIG. 13A; and FIG. 14C is a schematic top view of FIG. 14A.
The present disclosure provides a method for manufacturing a semiconductor structure. The method includes: providing a base substrate 10; forming bit line structures 20 on the base substrate 10, where the bit line structures 20 extend along a first direction X and are spaced apart from each other along a second direction Y, the first direction X is perpendicular to the second direction Y, and first openings 301 are formed between adjacent bit line structures 20; forming a first initial material layer 401′, where the first initial material layer 401′ covers the side walls and tops of the bit line structures 20 and the bottoms of the first openings 301; removing part of the first initial material layer 401′ by a first etching process to form a first material layer 401, where the thickness of first material layer 401 gradually increases from the top of the bit line structure 20 to a first position P1 at a first rate and gradually increases from the first position P1 to the bottom of the first material layer 401 at a second rate, the first rate being greater than the second rate; forming a second material layer 402, where the second material layer 402 covers the first material layer 401; forming a first initial dielectric layer 501′, where the first initial dielectric layer 501′ fills the remaining portions of the first openings 301; removing part of the first initial dielectric layer 501′ to form second openings 302, where the remaining first initial dielectric layers 501′ serve as first dielectric layers 501, and the first dielectric layers 501 and the second openings 302 are located between adjacent bit line structures 20 and spaced apart from each other along the first direction X; forming a second dielectric layer 502, where the second dielectric layer 502 fills the second openings 302; removing the first dielectric layer 501 to form third openings 303, where the third openings 303 are located between adjacent bit line structures 20, and the third openings 303 and the second dielectric layer 502 are spaced apart from each other along the first direction X; and performing etching by a second etching process with the third openings 303 as a mask to remove the first material layer 401 and the second material layer 402 above the first position P1 and form fourth openings 304 under the third openings 303, a third opening 303 and a fourth opening 304 together constituting a node contact hole 30.

Specifically, referring to FIGS. 4A and 4B, a method for forming a semiconductor structure includes: providing a base substrate 10. The base substrate 10 includes isolation structures 101, and active regions 102 are provided between adjacent isolation structures 101. As shown in FIG. 4B, word line structures 104 are further provided in the substrate; the word line structures 104 extend along the second direction Y, and adjacent word line structures 104 are spaced apart from each other along the first direction X. Bit line structures 20 are formed on the base substrate 10; the bit line structures 20 extend along the first direction X and are spaced apart from each other along the second direction Y, the bit line structure 20 is provided with a certain height in a third direction Z, the first direction X is perpendicular to the second direction Y, and first openings 301 are formed between adjacent bit line structures 20. In some embodiments, the bit line structure 20 includes a bit line conductive layer 201 and a bit line capping layer 202. The bit line capping layer 202 is located on the bit line conductive layer 201.

Referring to FIGS. 6A and 6B, a first initial material layer 401′ is formed, and the first initial material layer 401′ covers the side walls and tops of the bit line structures 20 and the bottoms of the first openings 301.

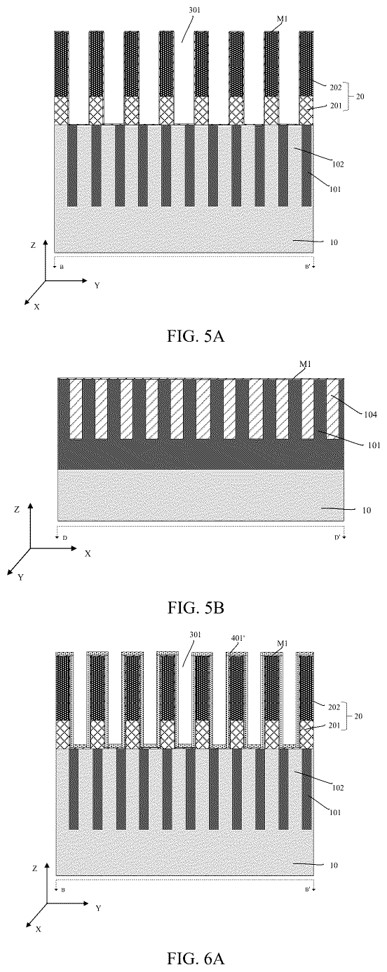

In some embodiments, referring to FIGS. 5A and 5B, before forming the first initial material layer 401′, the method further includes: forming a first protective layer M1. The first protective layer M1 covers the side walls and tops of the bit line structures 20 and the bottoms of the first openings 301. The first initial material layer 401′ covers the protective layer M1.

Referring to FIGS. 7A and 7B, part of the first initial material layer 401′ is removed by a first etching process to form a first material layer 401. The thickness of the first material layer 401 gradually increases from the top of the bit line structure 20 to a first position P1 at a first rate and gradually increases from the first position P1 to the bottom of the first material layer 401 at a second rate; the first rate is greater than the second rate. Specifically, as shown in FIG. 8, which is an enlarged view of a part circled in FIG. 7A, the first material layer 401 covers the top and side walls of the bit line structure 20. The thickness of the first material layer 401 on the side wall of the bit line structure 20 gradually increases from the top of the bit line structure 20 to the first position P1, with the rate of increase being a first rate; the thickness from the first position P1 to the bottom of the first material layer 401 also gradually increases, with the rate of increase being a second rate. The first rate is greater than the second rate. It should be noted that the thickness here refers to a distance along the Y direction. The bit line structure 20 includes a bit line conductive layer 201 and a bit line capping layer 202. The bit line capping layer 202 is located on the bit line conductive layer 201, and the first position P1 is close to the top of the bit line capping layer 202. In one specific embodiment, the height of the first position P1 is h, and the height of the bit line capping layer 202 is H, where 1/7H≤h≤2/5H. The height h here refers to the distance from the top of the bit line capping layer 202 to the first position P1.

In one specific embodiment, part of the first initial material layer 401′ is removed by a first etching process to form a first material layer 401. The etching gas for the first etching process is a mixed gas of fluoride, oxygen, and argon. The fluoride may be carbon tetrafluoride (CF4), sulfur hexafluoride (SF6), and a mixture thereof. The first etching process is divided into two stages. The etching power in the first stage is 400 W to 800 W, and the etching frequency is 10 MHz to 15 MHz; the etching power in the second stage is 50 W to 100 W, and the etching frequency is 1 MHz to 3 MHz. The etching power and the etching frequency in the first stage are both greater than the etching power and the etching frequency in the second stage.

During etching, etching power and etching frequency are two critical parameters. The etching power primarily influences the energy and density of particles in plasma. Higher power means more energy is inputted into the plasma, which increases the average energy of the particles (ions, electrons, radicals, etc.) in plasma, thereby increasing their reaction rate with the material on the wafer surface. The etching frequency primarily influences the generation and distribution of plasma as well as the movement of particles in the plasma. The etching frequency is divided into low frequency and high frequency. The low-frequency etching can provide higher ion energy, which is beneficial to enhance the etching capability of plasma in the perpendicular direction. For the etching of the side walls of trenches with high aspect ratios, the low-frequency etching can provide better anisotropic control, namely, enhancing the etching on an upper film layer. High-frequency plasma etching can produce a more uniform plasma distribution, which is critical to maintaining the anisotropy and uniformity of etching. According to the present disclosure, in the first stage, relatively large etching power and etching frequency are employed first, such that the first initial material layer 401′ is removed uniformly from the top to the bottom. However, since the aspect ratio of the first opening 301 is relatively large, the energy and density of the plasma at the bottom of the first opening 301 are bound to be less than those at the top, such that the top of the first initial material layer 401′ is removed relatively more, and the bottom is removed relatively less. Further, relatively low etching power and etching frequency are employed in the first stage, such that the ion energy of the plasma close to the top of the first opening 301 is relatively high, and the anisotropic etching capability is stronger, resulting in the removal of more of the first initial material layer 401′ close to both sides of the top of the first opening 301, thereby forming a platform with a rapidly transitioning thickness in the first material layer 401 on both sides of the top of the first opening 301. That is, the thickness change of the first material layer 401 above and below the first position P1 is significantly different. The thickness change rate from the top of the bit line structure 20 to the first position P1 is a first rate, and the thickness change rate from the first position P1 to the bottom of the first material layer 401 is a second rate; the first rate is greater than the second rate. This makes the top openings between adjacent first material layers 401 relatively large, thereby providing larger space for subsequent material filling and preventing the generation of air gaps. In one specific embodiment, the first rate is three to six times the second rate.

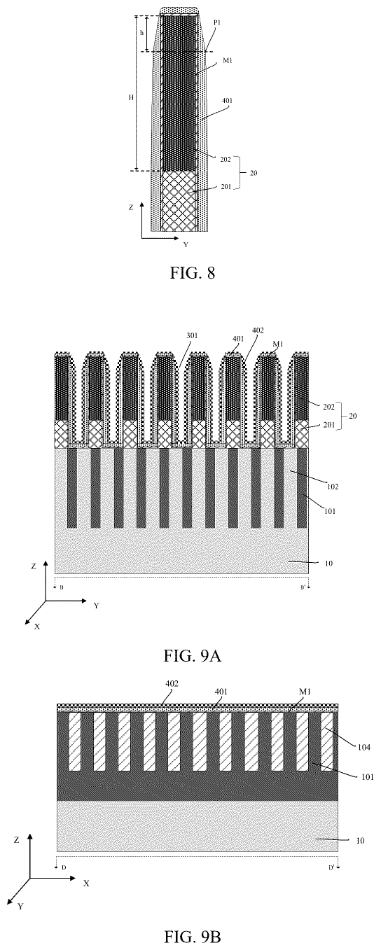

With further reference to FIGS. 9A and 9B, a second material layer 402 is formed, and the second material layer 402 covers the first material layer 401. In one specific embodiment, the first protective layer M1, the first material layer 401, and the second material layer 402 together constitute a protective layer of the bit line structure 20. The material of the first protective layer M1 may be silicon nitride (SiN) or silicon oxynitride (SiON), the material of the first material layer 401 may be silicon oxide (SiO₂), and the material of the second material layer 402 may be silicon nitride (SiN) or silicon oxynitride (SiON).

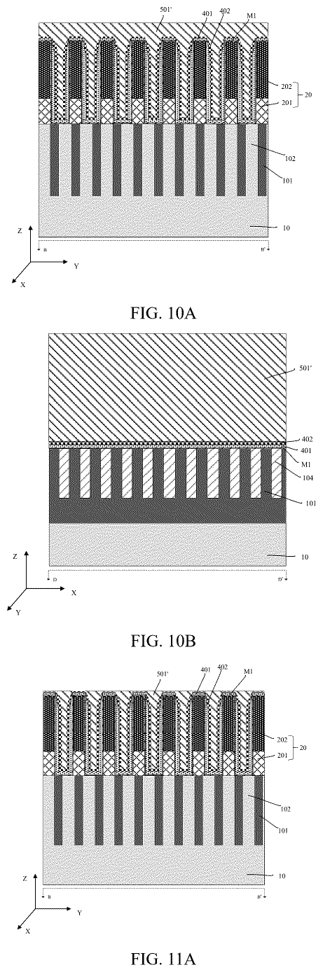

With further reference to FIGS. 10A to 12C, a first initial dielectric layer 501′ is formed, and the first initial dielectric layer 501′ fills the remaining portions of first openings 301; part of the first initial dielectric layer 501′ is removed to form second openings 302, the remaining first initial dielectric layers 501′ serve as first dielectric layers 501, and the first dielectric layers 501 and the second openings 302 are located between adjacent bit line structures 20 and spaced apart from each other along the first direction X.

Specifically, referring to FIGS. 10A and 10B, a first initial dielectric layer 501′ is formed first, and the first initial dielectric layer 501′ fills the remaining portions of first openings 301. As shown in FIG. 10A, the first initial dielectric layer 501′ further covers the top of the second material layer 402. Next, as shown in FIGS. 11A and 11B, part of the first initial dielectric layer 501′ is removed by chemical mechanical polishing to expose the top of the second material layer 402. Then, as shown in FIGS. 12A and 12C, part of the first initial dielectric layer 501′ is removed to form second openings 302. The remaining first initial dielectric layers 501′ serve as first dielectric layers 501, and the first dielectric layers 501 and the second openings 302 are located between adjacent bit line structures 20 and spaced apart from each other along the first direction X. It should be noted that FIG. 12C is a schematic top view of FIG. 12A, and for more explicit illustration, only the bit line structure 20 is shown in FIG. 12C and the second material layer 402 covering the bit line structure 20 is not shown.

With further reference to FIGS. 13A to 13C, a second dielectric layer 502 is formed, and the second dielectric layer 502 fills the second openings 302. In the direction BB′, there is no difference between FIGS. 13A and 12A. However, in the DD′ direction, the second dielectric layer 502 fills the second openings 302. As shown in the top view of FIG. 13C, the bit line structures 20 extend along the first direction X, the first dielectric layer 501 and the second dielectric layer 502 are located between two bit line structures 20, and the first dielectric layer 501 and the second dielectric layer 502 are spaced apart from each other between two bit line structures 20, which takes a checkerboard-like pattern as shown in FIG. 13C. Additionally, a plurality of first dielectric layers 501 are all spaced apart from the bit line structures 20 in the Y direction, and a plurality of second dielectric layers 502 are also spaced apart from the bit line structures 20.

With further reference to FIGS. 14A to 14C, the first dielectric layer 501 is removed to form third openings 303, the third openings 303 are located between adjacent bit line structures 20, and the third openings 303 and the second dielectric layer 502 are spaced apart from each other along the first direction X.

With further reference to FIGS. 15A to 17B, etching is performed by a second etching process with the third openings 303 as a mask to remove the first material layer 401 and the second material layer 402 above the first position P1 and form fourth openings 304 under the third openings 303. A third opening 303 and a fourth opening 304 together constitute a node contact hole 30. Removing the first material layer 401 and the second material layer 402 above the first position P1 and forming the fourth openings 304 under the third openings 303 specifically includes: a first etching process and a second etching process. The first etching process includes removing the first material layer 401 and the second material layer 402 above the first position P1; the second etching process includes forming the fourth openings 304.

Specifically, referring to FIGS. 15A and 15B, the first material layer 401 above the first position P1 is removed first, and part of the second dielectric layer 502 is also removed during the process of removing the first material layer 401 above the first position P1, resulting in the formation of rounded corners at the top of the second dielectric layer 502. The formation of rounded corners at the top of the second dielectric layer 502 enlarges the top openings between adjacent second dielectric layers 502, thereby enabling an easier subsequent filling and further preventing the generation of air gaps.

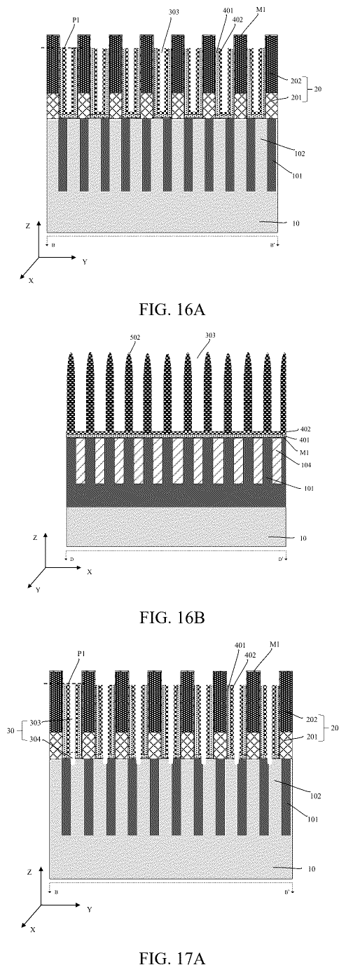

Referring to FIGS. 16A and 16B, the second material layer 402 above the first position P1 is continuously removed, such that the first material layer 401 and the second material layer 402 above the first position P1 are removed completely. In this case, the top openings between adjacent bit line structures 20 are further enlarged, providing further assurance for subsequent filling and further preventing the generation of air gaps. As described above, the first material layer 401 and the second material layer 402 above the first position P1 are removed primarily by the first etching process. The first etching process employs methyl fluoride and oxygen as etching gases, with an etching power of 550 W to 650 W and an etching frequency of 10 MHz to 15 MHz.

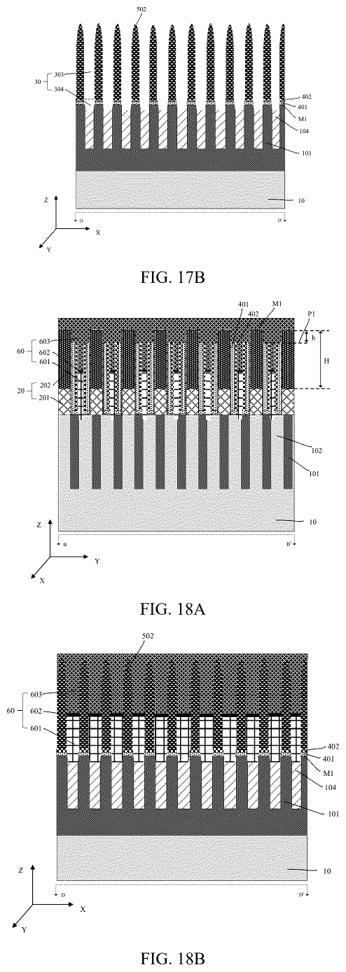

Referring to FIGS. 17A and 17B, the substrate 10 is further etched with the third openings 303 as a mask to form fourth openings 304, and the fourth openings 304 extend into the base substrate 10 and are located under the third openings 303. A third opening 303 and a fourth opening 304 together constitute a node contact hole 30. As described above, the fourth openings 304 are formed primarily by the second etching process. The second etching process employs hexafluorobutadiene, oxygen, and argon as etching gases. The second etching process first employs an etching power of 550 W to 650 W and an etching frequency of 10 MHz to 15 MHz, and then employs an etching power of 80 W to 120 W and an etching frequency of 1 MHz to 3 MHz. The formation of the fourth opening 304 increases the contact area between the subsequently formed contact structure and the active region 102, thereby improving the performance of the semiconductor structure.

With further reference to FIGS. 18A and 18B, a contact structure 601, a bonding structure 602, and a conductive structure 603 are formed in a node contact hole 30; the contact structure 601, the bonding structure 602, and the conductive structure 603 are sequentially arranged from bottom to top. The contact structure 601 at least fills the fourth opening 304. The contact structure 601 is configured to electrically connect to the active region 102, and the conductive structure 603 is configured to electrically connect to a capacitor structure subsequently formed. Since the adhesion between the contact structure 601 and the conductive structure 603 is relatively poor, the bonding structure 602 is used to enhance the adhesion performance between the contact structure 601 and the conductive structure 603. In one specific embodiment, the contact structure 601 may be polycrystalline silicon, the bonding structure 602 may be cobalt silicide or nickel silicide, and the conductive structure 603 may be titanium nitride or tungsten, or a stack of titanium nitride and tungsten. By adopting the contact structure 601, the bonding structure 602, and the conductive structure 603 manufactured according to the present disclosure, there is no air gap generated in these structures, that is, the present disclosure can avoid the phenomenon where the bonding structure 602 cannot be formed due to the presence of the air gap, thereby improving the conductive performance of the contact structure 31 and the conductive structure 33, as well as the overall performance of the semiconductor structure.

According to the present disclosure, part of a first initial material layer is removed by a first etching process to form a first material layer, the thickness of the first material layer gradually increases from the top of a bit line structure to a first position at a first rate and gradually increases from the first position to the bottom at a second rate; the first rate is greater than the second rate; a second material layer is formed, and the second material layer covers the first material layer; the first material layer and the second material layer above the first position are removed by a second etching process, and a fourth opening is formed under a third opening, the third opening and the fourth opening together constitute a node contact hole, such that the top opening of the node contact hole is enlarged, thereby preventing the generation of air gaps when a contact structure, a bonding structure, and a conductive structure are formed by subsequent filling, and thus improving the conductive performance of the conductive structure and the contact structure.

Another embodiment of the present disclosure further provides a semiconductor structure. Specifically, referring to FIGS. 17A to 18B, the semiconductor structure includes: a base substrate 10; bit line structures 20, formed on the base substrate 10, where the bit line structures 20 extend along a first direction X and are spaced apart from each other along a second direction Y, the first direction being perpendicular to the second direction Y; third openings 303 and a second dielectric layer 502, provided between adjacent bit line structures 20, where the third openings 303 and the second dielectric layer 502 are spaced apart from each other along the first direction X; fourth openings 304, formed under the third openings 303, where a third opening 303 and a fourth opening 304 together constitute a node contact hole 30, and the fourth opening 304 has an inverted trapezoid shape; a first material layer 401, covering the side walls of the bit line structures 20, where the first material layer 401 extends from the first position P1 of the bit line structure 20 to the bottom of the bit line structure 20; and a second material layer 402, covering the first material layer 401, where the bit line structure 20 from the top to the first position P1 is not covered by the first material layer 401 and the second material layer 402. A contact structure 601, a bonding structure 602, and a conductive structure 603 are sequentially arranged from bottom to top in the node contact hole 30. The contact structure 601 at least fills the fourth opening 304. The top of the second dielectric layer 502 is a rounded corner. The bit line structure 20 includes a bit line conductive layer 201 and a bit line capping layer 202, and the bit line capping layer 202 is located on the bit line conductive layer 201. The first position P1 is close to the top of the bit line cladding layer 202, the height of the first position is h, and h here refers to the distance from the top of the bit line capping layer 202 to the first position P1; the height of the bit line capping layer is H, and H here refers to the distance from the first position P1 to the bottom of the bit line capping layer 202, where 1/7H≤h≤2/5H.

According to the semiconductor structure of the present disclosure, since the bit line structure 20 from the top to the first position P1 is not covered by the first material layer 401 and the second material layer 402, and the top of the second dielectric layer 502 is a rounded corner, the top opening between adjacent bit line structures 20 is relatively large, such that the generation of an air gap can be prevented in the process of forming the contact structure 601 by filling. Since the air gap is not generated, the bonding structure 602 is easier to generate, thereby preventing the disappearance of the bonding structure 602. The bonding structure 602 serves to improve the adhesion performance between the contact structure 601 and the conductive structure 603, and the easier formation of the bonding structure 602 ensures the adhesion performance between the contact structure 601 and the conductive structure 603. Further, a conductive structure 603 is formed on the bonding structure 602, and the conductive structure 603 is also free of the air gap, thereby improving the conductive performance of both the conductive structure 603 and the contact structure 601 and further improving the performance of the whole semiconductor device.

Those of ordinary skill in the art can understand that the foregoing implementations are specific embodiments of practicing the present disclosure, while in practical application, various changes can be made to the implementations in form and detail without departing from the spirit and scope of the present disclosure. Any person skilled in the art can make various changes and modifications without departing from the spirit and scope of the present disclosure, and the protection scope of the present disclosure shall be defined by the appended claims.

What is claimed is:

1. A method for manufacturing a semiconductor structure, comprising:
providing a base substrate;
forming bit line structures on the base substrate, wherein the bit line structures extend along a first direction and are spaced apart from each other along a second direction, the first direction is perpendicular to the second direction, and first openings are provided between adjacent bit line structures;
forming a first initial material layer, wherein the first initial material layer covers side walls and tops of the bit line structures and bottoms of the first openings;
removing part of the first initial material layer by a first etching process to form a first material layer, wherein a thickness of the first material layer gradually increases from each of the tops of each of the bit line structures to a first position at a first rate and gradually increases from the first position to a bottom of the first material layer at a second rate; the first rate is greater than the second rate;
forming a second material layer, wherein the second material layer covers the first material layer;
forming a first initial dielectric layer, the first initial dielectric layer filling remaining portions of the first openings; removing part of the first initial dielectric layer to form second openings, wherein remaining first initial dielectric layers serve as first dielectric layers, and the first dielectric layers and the second openings are located between adjacent bit line structures and spaced apart from each other along the first direction;
forming a second dielectric layer, wherein the second dielectric layer fills the second openings;
removing the first dielectric layers to form third openings, wherein the third openings are located between adjacent bit line structures, and the third openings and the second dielectric layer are spaced apart from each other along the first direction; and
performing etching by a second etching process with the third openings as a mask to remove the first material layer and the second material layer above the first position and form fourth openings under the third openings, wherein each of the third openings and each of the fourth openings together constitute a node contact hole.

2. The method for manufacturing the semiconductor structure according to claim 1, further comprising: forming a contact structure, a bonding structure, and a conductive structure in the node contact hole, wherein the contact structure, the bonding structure, and the conductive structure are sequentially arranged from bottom to top, and the contact structure at least fills the fourth opening.

3. The method for manufacturing the semiconductor structure according to claim 1, wherein performing the etching by the second etching process with the third openings as the mask further comprises: removing part of the second dielectric layer to form a rounded corner at a top of the second dielectric layer.

4. The method for manufacturing the semiconductor structure according to claim 1, wherein each of the bit line structures comprises a bit line conductive layer and a bit line capping layer, the bit line capping layer being located on the bit line conductive layer; the first position is close to a top of the bit line capping layer.

5. The method for manufacturing the semiconductor structure according to claim 4, wherein a height of the first position is h, and a height of the bit line capping layer is H, wherein
$$\frac{1}{7} H \leq h \leq \frac{2}{5} H .$$

6. The method for manufacturing the semiconductor structure according to claim 1, wherein an etching gas for the first etching process is a mixed gas of fluoride, oxygen, and argon; the first etching process is divided into two stages, wherein in a first stage, an etching power is 400 W to 800 W, and an etching frequency is 10 MHz to 15 MHz; in a second stage, an etching power is 50 W to 100 W, and an etching frequency is 1 MHz to 3 MHz.

7. The method for manufacturing the semiconductor structure according to claim 1, wherein removing the first material layer and the second material layer above the first position and forming the fourth openings under the third openings specifically comprises: a first etching process and a second etching process, wherein the first etching process comprises removing the first material layer and the second material layer above the first position; the second etching process comprises forming the fourth openings.

8. The method for manufacturing the semiconductor structure according to claim 7, wherein the first etching process employs methyl fluoride and oxygen as etching gases, with an etching power of 550 W to 650 W and an etching frequency of 10 MHz to 15 MHz.

9. The method for manufacturing the semiconductor structure according to claim 7, wherein the second etching process employs hexafluorobutadiene, oxygen, and argon as etching gases; the second etching process first employs an etching power of 550 W to 650 W and an etching frequency of 10 MHz to 15 MHz, and then employs an etching power of 80 W to 120 W and an etching frequency of 1 MHz to 3 MHz.

10. A semiconductor structure, comprising:
a base substrate;
bit line structures, formed on the base substrate, wherein the bit line structures extend along a first direction and are spaced apart from each other along a second direction, the first direction being perpendicular to the second direction;
third openings and a second dielectric layer, provided between adjacent bit line structures, wherein the third openings and the second dielectric layer are spaced apart from each other along the first direction;
fourth openings, formed under the third openings, wherein each of the third openings and each of the fourth openings together constitute a node contact hole;
a first material layer, covering side walls of the bit line structures, wherein the first material layer extends from a first position of each of the bit line structures to a bottom of the bit line structure; and
a second material layer, covering the first material layer, wherein
the bit line structure from a top to the first position is not covered by the first material layer and the second material layer.

11. The semiconductor structure according to claim 10, further comprising: a contact structure, a bonding structure, and a conductive structure, wherein the contact structure, the bonding structure, and the conductive structure are sequentially arranged from bottom to top in the node contact hole, and the contact structure at least fills the fourth opening.

12. The semiconductor structure according to claim 10, wherein a top of the second dielectric layer is a rounded corner.

13. The semiconductor structure according to claim 10, wherein each of the bit line structures comprises a bit line conductive layer and a bit line capping layer, the bit line capping layer being located on the bit line conductive layer; the first position is close to a top of the bit line capping layer.

14. The semiconductor structure according to claim 13, wherein a height of the first position is h, and a height of the bit line capping layer is H, where 1/7H≤h≤2/5H.

15. The semiconductor structure according to claim 10, wherein the fourth opening has an inverted trapezoid shape.
